(19) United States
(12) Patent Application Publication
(10) Pub. No.: US 2022/0359279 A1
(43) Pub. Date: Nov. 10, 2022

(54) METHODS OF FORMING VOID AND SEAM FREE METAL FEATURES

(71) Applicant: Applied Materials, Inc., Santa Clara, CA (US)

(72) Inventors: Xi CEN, San Jose, CA (US); Mingrui ZHAO, Newark, CA (US); Peiqi WANG, Campbell, CA (US); Wei Min CHAN, Sunnyvale, CA (US); Kai WU, Palo Alto, CA (US); Yi LUO, Santa Clara, CA (US); Liqi WU, San Jose, CA (US)

(21) Appl. No.: 17/316,649

(22) Filed: May 10, 2021

(51) Int. Cl. H01L 21/768; C23C 16/455; C23C 16/06

(52) U.S. Cl. CPC H01L 21/76876; C23C 16/45536; C23C 16/45544; C23C 16/06

(57) ABSTRACT

Embodiments herein are generally directed to methods of forming high aspect ratio metal contacts and/or interconnect features, e.g., tungsten features, in a semiconductor device. Often, conformal deposition of tungsten in a high aspect ratio opening results in a seam and/or void where the outward growth of tungsten from one or more walls of the opening meet. Thus, the methods set forth herein provide for a desirable bottom up tungsten bulk fill to avoid the formation of seams and/or voids in the resulting interconnect features, and provide an improved contact metal structure and method of forming the same. In some embodiments, an improved overburden layer or overburden layer structure is formed over the field region of the substrate to enable the formation of a contact or interconnect structure that has improved characteristics over conventionally formed contacts or interconnect structures.

### BACKGROUND

### Field

Embodiments described herein generally relate to the field of semiconductor device manufacturing, and more particularly, to methods of treating a nucleation layer that includes tungsten containing materials.

### Description of the Related Art

Due to its low resistivity and high melting point, tungsten (W) is commonly used as a fill material to form many of the conductive features within a semiconductor device. Tungsten is often used to form interconnect features, such as vias, and to fill source and drain contacts. Typically, tungsten containing features are formed in the layers of materials, such as silicon or dielectrics, disposed on a substrate.

To prevent diffusion and promote adhesion of tungsten material thereto, one or more layers of a barrier material, e.g., titanium (Ti) and/or titanium nitride (TiN), are deposited onto a dielectric layer to line openings therein. A tungsten film is then formed over the barrier material. Unfortunately, depositing tungsten into increasingly smaller features using conventional methods often results in the undesirable formation of seams and/or voids in the resulting interconnect feature, and an overburden over the substrate surface outside of the feature. To maintain a tungsten film coplanar with the surface of the surrounding silicon or dielectric layer outside of the feature, the substrate surface is planarized to remove the overburden of tungsten from the field surface.

The seams and/or voids result from the conformal deposition of a tungsten layer on the field surface of the substrate and in the opening formed thereon. As the tungsten layer grows from all surfaces simultaneously, and at the same rate, two problems can occur. First, the tungsten forming on the walls of the opening near the surface can grow together prematurely pinching off the opening and creating a space that is empty of tungsten in a portion of the opening there beneath, i.e., a void. Second, as the tungsten deposited on the walls of the opening grows together simultaneously, the growth pattern can create a seam which extends upwardly through the feature. Once formed, these seams and/or voids may lead to degraded performance, reliability and/or suppressed yield, as corrosive chemistries used in post deposition processes, such as chemical mechanical planarization (CMP) or tungsten etchback, may further open existing seams and voids.

Another challenge to the deposition of tungsten material in features and field surfaces is stress. High stress in tungsten fill material can result in undesirable deformation of interconnects. In regions of high feature density, adjacent features having a high aspect ratio, and high stress in the tungsten fill and overburden layer can cause deformation of the silicon or dielectric material disposed between the features. For example, high stress in the tungsten fill or overburden layer may cause the deformation of silicon fins disposed between tungsten buried word lines (bWL) in a memory device, otherwise known as undesirable line bending. Deformation of silicon or dielectric materials disposed between tungsten features can result in undesirable offsets with subsequently formed interconnect features resulting in shorts and open circuits and reliability and functionality problems associated therewith.

In addition, undesirably high stress tungsten films may cause deformation, such as warping, of the underlying substrate. Deformation of the underlying substrate makes subsequent processing, such as a CMP process, difficult and can contribute to inconsistent processing results. Conventional methods of reducing stress in films of other materials, such as annealing, are generally unavailable for reducing the stress of tungsten films in a semiconductor device manufacturing process as tungsten does not have the surface mobility to allow grains to be moved or altered at temperatures that are suitably low enough to not cause damage to the devices formed therefrom.

Accordingly, there is a need in the art for improved methods of forming conductive features in semiconductor devices that solve the problems described above.

### SUMMARY

Embodiments of the disclosure provide for methods of depositing a film that include depositing a tungsten bulk fill material into a plurality of openings on a substrate by exposing the substrate to a first tungsten-containing precursor gas and a first reducing agent at or below a first processing pressure, and depositing a first tungsten overburden layer over the tungsten bulk fill material. The substrate includes a first material layer having a plurality of openings formed therein and a tungsten nucleation layer formed on the first material layer to conformally line the plurality of openings. Depositing the first tungsten overburden layer over the tungsten bulk fill material includes exposing the substrate to a second tungsten-containing precursor gas and a second reducing agent at a second processing pressure, wherein the second processing pressure is at least three times greater than the first processing pressure.

Embodiments of the disclosure also provide for an additional method of depositing a film that includes depositing a tungsten bulk fill material into a plurality of openings formed in a first material layer of a substrate by concurrently flowing a first tungsten-containing precursor gas, and a first reducing agent, into a first processing volume, and exposing the substrate thereto while maintaining the first processing volume at a first processing volume at a first processing pressure. The method further includes depositing a first tungsten overburden layer onto the tungsten bulk fill material and a field surface of the substrate. Depositing the first tungsten overburden layer onto the tungsten bulk fill material and field surface includes exposing the substrate to alternating pulses of a second tungsten-containing precursor gas and a second reducing agent in a second processing volume while maintaining the second processing volume at a second processing pressure, wherein the second processing pressure is at least three times greater than the first processing pressure.

Embodiments of the disclosure also provide for a substrate processing system that includes a first process chamber, a second process chamber, a transfer chamber coupling the first processing chamber to the second process chamber, and a non-transitory computer readable medium having instructions stored thereon for performing a method of processing a substrate when executed by a processor. The method includes depositing a material layer having a plurality of openings formed therein, depositing a tungsten bulk fill material into the plurality of openings by exposing the substrate to a first tungsten-containing precursor gas and a first reducing agent at or below a first processing pressure, and depositing a first tungsten overburden layer over the tungsten bulk fill material. The deposition of the first tungsten overburden layer includes exposing the substrate to a second tungsten-containing precursor gas, and a second reducing agent at a second processing pressure, wherein the second processing pressure is at least three times greater than the first processing pressure. The deposition of the material layer into the plurality of openings occurs in a first process chamber, and the deposition of a tungsten bulk fill material into the plurality of openings occurs in a second process chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A-1B are schematic cross-sectional views of a substrate illustrating the formation of undesirable seams and voids in an interconnect feature.

FIG. 2 is a schematic cross-sectional view of an exemplary processing chamber used to practice the methods set forth herein.

FIG. 3 is a schematic plan view of a multi-chamber processing system which may be used to perform the methods set forth herein.

FIG. 4 is a block diagram of a method of forming a conductive feature of an electronic device, according to one embodiment.

FIGS. 5A-5E are schematic cross-sectional views of a substrate illustrating various aspects of the method of FIG. 4.

FIG. 6 is a graph showing the film stress of bulk layers of tungsten deposited according to various methods disclosed herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments herein are generally directed to methods of forming high aspect ratio metal contacts and/or interconnect features, e.g., tungsten features, in a semiconductor device. Often, conformal deposition of tungsten in a high aspect ratio opening results in a seam and/or void where the outward growth of tungsten from one or more walls of the opening meet. Thus, the methods set forth herein provide for a desirable bottom up tungsten bulk fill to avoid the formation of seams and/or voids in the resulting interconnect features, and provide an improved contact metal structure and method of forming the same. In some embodiments, an improved overburden layer or overburden layer structure is formed over the field region of the substrate to enable the formation of a contact or interconnect structure that has improved characteristics over conventionally formed contacts or interconnect structures.

The methods provided herein include treating a field surface of the substrate with a radical species to inhibit the growth of tungsten at the field surface and in the walls of upper portions of openings formed in the field surface. The methods provided herein create a gradient of inhibition for tungsten formation. By creating a gradient of inhibition for tungsten formation, tungsten growth in the deepest portion of the openings is less inhibited than at the field surface, resulting in a desirable bottom up growth of a subsequent bulk fill and beneficial seamless and voidless tungsten features. The formed seamless and voidless tungsten features include the formation of one or more overburden layers that have desirable properties as described further below.

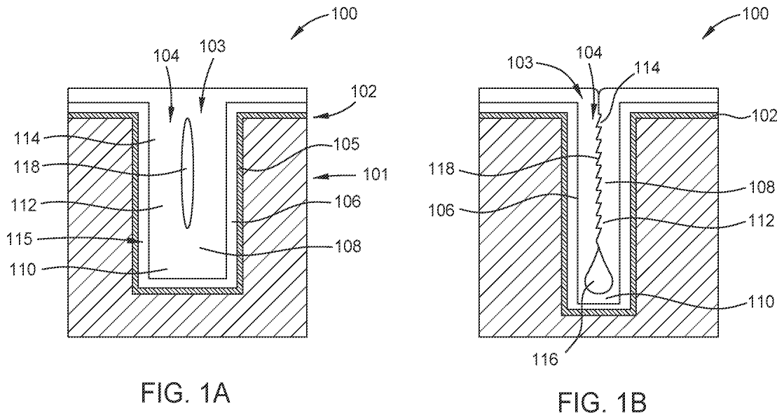

FIGS. 1A and 1B are cross-sectional views of a substrate 100 illustrating conventionally formed tungsten vias that include undesirable seams or voids formed therein. Here, the substrate 100 includes a dielectric layer 101 having a plurality of openings 103 (one shown) formed therein, and a plurality of tungsten interconnect features 104 (one shown), formed in the openings 103. In some embodiments, the tungsten interconnect feature 104 formed in the opening 103 has a width of about 8 nm or less and height of about 110 nm or more. In some embodiments, the tungsten interconnect feature has an aspect ratio of about 25:1 or more.

Here, the opening 103 and a field surface 102 of the dielectric layer 101 is lined with a barrier material layer 105 which may be deposited by reacting a precursor at or over the exposed field surface 102 and the opening 103 to line the opening 103, and block diffusion of a subsequently deposited tungsten fill layer 108 into the surrounding dielectric layer 101. The barrier material layer 105 may also promote adhesion between the tungsten fill layer 108 and the walls 115 of the openings 103.

A nucleation layer 106 may then be deposited over the barrier material layer 105 by reacting a precursor at or over the exposed field surface 102 and the opening 103. The nucleation layer 106 may be a thin conformal layer deposited by an atomic layer deposition (ALD) process. However, in other embodiments a chemical vapor deposition (CVD) process may be used. The nucleation layer 106 may be used to promote the initiation, growth and adhesion of the tungsten fill layer 108 to the barrier material layer 105.

The tungsten fill layer 108 is then deposited over the nucleation layer 106. The tungsten fill layer 108 is deposited conformally over the nucleation layer 106. As the layer grows from all surfaces simultaneously and at the same rate, two problems can occur. First, portions of the tungsten interconnect feature 104 can grow together simultaneously. This growth pattern in the tungsten interconnect feature 104 can create a seam 118 which forms when the growth from the tungsten fill layer 108 meets (FIG. 1A). The seam 118 creates space for post-processing reactants to damage the uniformity of the tungsten fill layer 108, such as those used in conjunction with CMP. Second, where the width of a lower portion 110 of the opening 103 is wider than the width of a middle portion 112 or at an upper portion 114, the middle portion 112 or the upper portion 114 can grow together prematurely creating an undesirable void 116 (FIG. 1B).

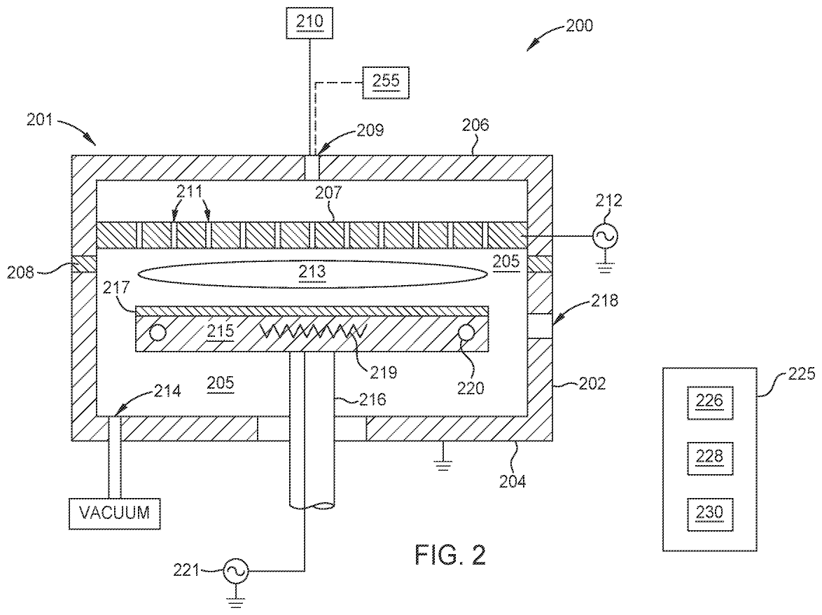

Accordingly, embodiments described herein provide for bottom-up tungsten fill when forming tungsten features that substantially reduce and/or eliminate pinch points at the feature opening to provide for seam-free and void-free tungsten features formed therefrom. An exemplary processing system which may be used to perform aspects of the methods is illustrated in FIG. 2.

### Processing Hardware Examples

FIG. 2 is a schematic cross sectional view of an exemplary processing chamber 200 used to practice the methods set forth herein, according to one embodiment. Other exemplary deposition chambers that may be used to practice the methods described herein include a Producer® ETERNA CVD® system, an Ultima HDP CVD® system, a CENTURA® Isprint ALD/CVD SSW, or other integrated tools available from Applied Materials, Inc., of Santa Clara, Calif. as well as suitable deposition chambers from other manufacturers.

The processing chamber 200 includes a chamber lid assembly 201, one or more sidewalls 202, and a chamber base 204. The chamber lid assembly 201 includes a chamber lid 206, a showerhead 207 disposed in the chamber lid 206, and an electrically insulating ring 208, disposed between the chamber lid 206 and the one or more sidewalls 202. The showerhead 207, one or more sidewalls 202, and the chamber base 204 together define a processing volume 205. A gas inlet 209, disposed through the chamber lid 206 is fluidly coupled to a gas source 210. The showerhead 207, having a plurality of openings 211 disposed therethrough, is used to uniformly distribute processing gases from the gas source 210 into the processing volume 205. In some embodiments, the showerhead 207 is electrically coupled to a first power supply 212, such as an RF power supply, which supplies power to ignite and maintain a plasma 213 of the processing gas through capacitive coupling therewith. In other embodiments, the processing chamber 200 comprises an inductive plasma generator and the plasma is formed through inductively coupling an RF power to the processing gas.

The processing volume 205 is fluidly coupled to a vacuum source, such as to one or more dedicated vacuum pumps, through a vacuum outlet 214, which maintains the processing volume 205 at sub-atmospheric conditions and evacuates the processing gas and other gases therefrom. A substrate support 215, disposed in the processing volume 205, is disposed on a movable support shaft 216 sealingly extending through the chamber base 204, such as being surrounded by bellows (not shown) in the region below the chamber base 204. Herein, the processing chamber 200 is conventionally configured to facilitate transferring of a substrate 217 to and from the substrate support 215 through an opening 218 in one of the one or more sidewalls 202, which is conventionally sealed with a door or a valve (not shown) during substrate processing.

Herein, a substrate 217, disposed on the substrate support 215, is maintained at a desired processing temperature using one or both of a heater, such as a resistive heating element 219, and one or more cooling channels 220 disposed in the substrate support 215. Typically, the one or more cooling channels 220 are fluidly coupled to a coolant source (not shown), such as a modified water source having relatively high electrical resistance or a refrigerant source. In some embodiments, the substrate support 215 or one or more electrodes thereof (not shown) is electrically coupled to a second power supply 221, such as a continuous wave (CW) RF power supply or a pulsed RF power supply, which supplies a bias voltage thereto.

Operation of the processing chamber 200 is facilitated by a system controller 225. They system controller 225 includes a programmable central processing unit (CPU) 226, which is operable with a memory 228 (e.g., non-volatile memory) and support circuits 230. The CPU 126 is one of any form of general purpose computer processor used in an industrial setting, such as a programmable logic controller (PLC), for controlling various chamber components and sub-processors. The memory 228, coupled to the CPU 226, facilitates the operation of the processing chamber 200. The support circuits 230 are conventionally coupled to the CPU 226 and comprise cache, clock circuits, input/output subsystems, power supplies, and the like, and combinations thereof coupled to the various components the processing chamber, to facilitate control of substrate processing operations therewith.

Here, the instructions in the memory 228 are in the form of a program product such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

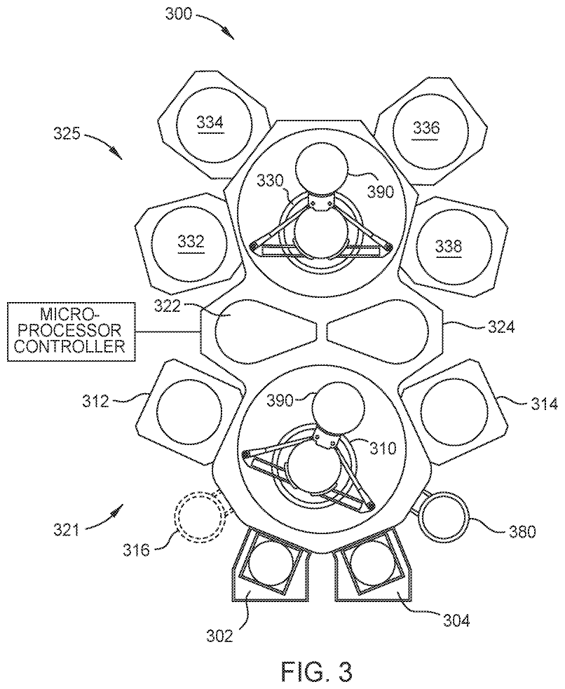

FIG. 3 is a schematic top view diagram of an multi-chamber processing system 300 that can be adapted to perform a metal layer deposition process as described herein having a processing chamber 380, such as the processing chamber 200 described above in reference to FIG. 2, integrated therewith. The multi-chamber processing system 300 can include one or more chambers 302 and 304 for transferring substrates 390 into and out of the multi-chamber processing system 300. Generally, the multi-chamber processing system 300 is maintained under vacuum and chambers 302 and 304 can be “pumped down” to introduce substrates 390 introduced into the multi-chamber processing system 300. A first robot 310 can transfer the substrates 390 between chambers 302 and 304, and a first set of one or more substrate processing chambers 312, 314, 316, and 380. Each processing chamber 312, 314, 316 and 380 is configured to perform at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, and other substrate processes. Furthermore, one of the processing chambers 312, 314, 316 and 380 may also be configured to perform a pre-clean process prior to performing a deposition process or a thermal annealing process on the substrate 390. The position of the processing chamber 380 may be optionally switched with any one of the processing chambers 312, 314, 316 if desired.

The first robot 310, which is positioned in a first transfer chamber 321, can also transfer substrates 390 to/from one or more pass-thru chambers 322 and 324. The pass-thru chambers 322 and 324 can be used to maintain ultrahigh vacuum conditions while allowing substrates 390 to be transferred within the multi-chamber processing system 300. A second robot 330, which is positioned in a second transfer chamber 325, can transfer the substrates 390 between the pass-thru chambers 322 and 324 and a second set of one or more processing chambers 332, 334, 336, 338. Similar to the processing chambers 312, 314, 316, 380, the processing chambers 332, 334, 336, and 338, can be outfitted to perform a variety of substrate processing operations including the dry etch processes described herein in addition to cyclical layer deposition (CLD), atomic layer deposition (ALD), chemical vapor deposition (CVD), physical vapor deposition (PVD), etch, pre-clean, degas, and orientation, for example. Any of the substrate processing chambers 312, 314, 316, 332, 334, 336, and 338 can be removed from the multi-chamber processing system 300 to perform other process as needed.

### Processing Methods

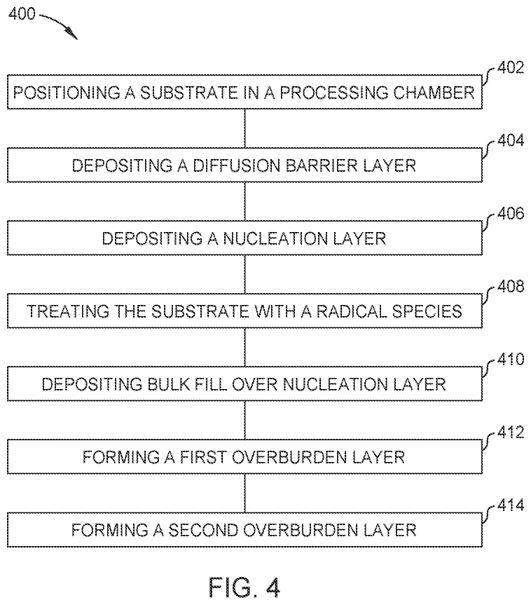

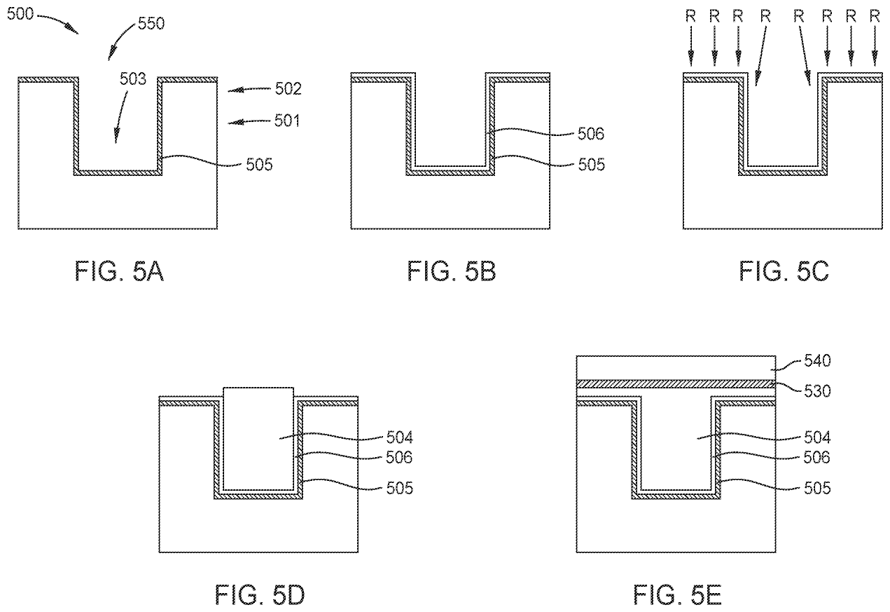

FIG. 4 is a block diagram of a method of forming a conductive feature of an electronic device, according to at least one embodiment. FIGS. 5A-5E schematically illustrate various aspects of the method 400. It is contemplated that the method 400, or various aspects thereof, may be performed using the processing chamber 200 and/or the multi-chamber processing system 300 described above, although other suitable chambers may be used.

At activity 402, the method 400 includes positioning a substrate in a first processing chamber 302, such as the processing chamber 200 described above. The substrate 500 can be of any suitable composition, such as a crystalline silicon wafer having one or more dielectric layers deposited thereon, and a plurality of openings formed in a field surface 502 of the one or more dielectric layers 501.

At activity 404, the method 400 includes depositing a diffusion barrier layer 505 onto the field surface 502 of a substrate 500, such as the substrate 500 shown in FIG. 5A. Here, the substrate 500 has a plurality of openings 503 (one shown) formed in the field surface 502 and the diffusion barrier layer 505 is deposited such that it lines the openings 503. The diffusion barrier layer 505 facilitates subsequent deposition of tungsten, in the openings, which otherwise would not occur on the surface of bare silicon, oxidized silicon, or silicon oxide dielectric layers absent unsuitably high temperatures for semiconductor device manufacturing schemes. In some embodiments, the diffusion barrier layer 505 comprises a titanium containing material, such as titanium nitride (TiN). In some embodiments, the diffusion barrier layer 505 is deposited to a thickness within a range from about 2 angstroms (Å) to about 100 Å. The diffusion barrier layer 505 can be deposited using any suitable process such as chemical vapor deposition (CVD), atomic layer deposition (ALD), or physical vapor deposition (PVD).

Generally, one or both of the CVD or ALD process may be plasma enhanced, where the method includes forming a plasma of one or both of the precursors to form radical species thereof and exposing the substrate to the plasma and/or radical species formed therefrom. The plasma may be in-situ (formed in the processing volume), or may be formed remotely from the substrate, e.g., by use of a remote plasma source.

In one embodiment, a CVD process used to form the diffusion barrier layer 505 includes reacting a titanium precursor, such as TiCl₄, and a nitrogen precursor, such as N₂ or NH₃, at a surface of the substrate. In another embodiment, an ALD process includes exposing the field surface 502 to a titanium precursor, such as TiCl₄, or a titanium-organic precursor comprising carbon, and a nitrogen precursor, such as N₂, or NH₃ in one cycle, purging the mixture from the process region of the chamber and then repeating the process steps. In some embodiments, the diffusion barrier layer 505 is deposited using a plasma enhanced PVD process where plasma excited species of a sputtering gas are used to bombard a titanium target and sputter titanium atoms therefrom. The titanium atoms are deposited on the field surface 502 in the presence of a nitrogen precursor, such as N₂, to form the diffusion barrier layer 505. In other embodiments, one or both of the CVD or ALD processes are thermal processes, for example, where the substrate is heated to promote reactions at the surface thereof versus using a plasma enhanced deposition process.

In some embodiments, the diffusion barrier layer 505 is deposited onto a substrate disposed in the first processing chamber 302 of the multi-chamber processing system 300 before the substrate is transferred to the second processing chamber 304 for the formation of a nucleation layer 506 at activity 406. In other embodiments, the diffusion barrier layer 505 and the nucleation layer 506 are sequentially formed in the same processing chamber. In some embodiments, the diffusion barrier layer 505 may function as the nucleation layer 506 for conformal growth of a thin tungsten film to be subsequently deposited. When the diffusion barrier layer 505 functions as a nucleation layer, the layer is typically a thin conformal layer enabling subsequent deposition of a bulk tungsten containing material thereon. In some embodiments where the diffusion barrier layer 505 functions as a nucleation layer the method may not include activity 406.

At activity 406, the method 400 includes forming a nucleation layer 506 on the diffusion barrier layer 505 (FIG. 5B). In one embodiment, the nucleation layer 506 is formed on the diffusion barrier layer 505 using an ALD process. The nucleation layer 506 may have a thickness that is at least a monolayer thick, such as a thickness between 20 angstroms (Å) and 200 Å, such as a thickness between 30 Å and 160 Å, such as a thickness between 40 Å and 130 Å, such as a thickness between 50 Å and 100 Å. In some embodiments, the ALD process includes repeating cycles of exposing the substrate to a tungsten-containing reduction agent, such as hydrogen (H₂). Examples of suitable tungsten-containing precursors include tungsten halides, such as tungsten hexafluoride (WF₆), tungsten hexachloride (WCl₆), or combinations thereof. Examples of suitable hydrogen-containing reducing agents include boranes and silanes, e.g., B₂H₆, SiH₄, Si₂H₆, or combinations thereof.

At activity 408, the method 400 includes treating the nucleation layer 506 to inhibit the deposition of tungsten according to an inhibition profile on a field surface of the substrate at activity 410. In some embodiments, treating the nucleation layer 506 includes exposing the substrate to a radical species R, such as radicals formed from a plasma activated treatment gas, such as N₂, H₂, NH₃, NH₄, O₂, CH₄, or a combination thereof (FIG. 5C). In at least one embodiment, the radical species is formed from a plasma activated nitrogen containing gas, such as N₂, H₂, NH₃, NH₄ or a combination thereof. The plasma may be in-situ (formed in the processing volume), or may be formed remotely from the substrate, by use of a remote plasma source 255 as shown in the processing chamber 200 of FIG. 2.

Referring back to FIG. 2, in one embodiment, the radical species R is formed by flowing the treatment gas into the remote plasma source 255 fluidly coupled to the processing volume 205 and igniting and maintaining a plasma of the treatment gas to form a radical species R thereof. The radical species R is then flowed into the processing volume and the substrate is exposed thereto. A typical flowrate of treatment gas to the remote plasma source 255 for processing of a 300 mm diameter substrate is between 10 sccm and 5000 sccm, such as between about 100 sccm and about 1500 sccm or between about 1 and about 100 sccm. Appropriate scaling may be used for different sized substrates. In at least one embodiment, the processing volume 205 is maintained at a pressure between about 900 mTorr and 120 Torr, or between about 1 Torr and 100 Torr, or between about 1 Torr and 50 Torr, or for example, between about 1 Torr and 10 Torr.

In some embodiments a remote plasma may be formed in a portion of the processing volume that is separated from the substrate processing portion by a showerhead, such as the showerhead 207. In this configuration, the effluent from the remote plasma source 255 is flowed through an ion filter to remove substantially all ions therefrom before the treatment radicals reach the processing volume and the surface of the substrate disposed therein. In embodiments where the plasma is formed in a separate portion of the processing volume a showerhead, such as the showerhead 207 in FIG. 2, disposed between the remote plasma and the substrate processing portion may be used as the ion filter. In other embodiments, the plasma used to form the treatment radicals is an in-situ plasma formed in the processing volume, for example, between the showerhead 207 and the substrate.

In at least one embodiment, the activated nitrogen is delivered to the surface of the substrate and reacts with the metallic tungsten to form WN. When the nitrogen is delivered as a plasma, it is delivered either with no bias or a low bias, to minimize the amount of nitrogen reacting with material at the bottom of features and thus not significantly inhibiting the material in these regions of the feature. It is preferred to use higher incubation times of the nitrogen containing-gas as opposed to lower incubation times. Without intending to be bound by theory, it is believed that the nitrogen requires a time above 10 seconds to properly incorporate into the nucleation layer 506. Diffusion of the nitrogen into the feature formed on the substrate is controlled by the energy level of the gas, the directionality of the gas, the size of the feature and the aspect ratio of the feature.

Beneficially, the radical treatment of the nucleation layer 506 slows down, or at least partially inhibits the growth of tungsten on regions that were significantly exposed to the nitrogen containing gas, such as the field surface 502 and upper portion of the feature (i.e., openings 503). For patterned substrates, such as those having high aspect ratio openings formed in the surface thereof, the radical treatment at activity 408 provides selective radical element exposure on the field surface 502, such that there is a higher delay or suppression of tungsten growth on the field surface 502 and upper portion of the openings 503, when compared to the lower portion and bottom of the openings 503.

In at least one embodiment, the radical treatment of the substrate should be such that the field surface 502 of the substrate should have a greater treatment when compared to the inside of one or more of the features. Because the final result is a high comparative tungsten nucleation delay on the field surface 502 as compared to nucleation in the lower portion of the openings 503, once tungsten growth is established in the feature, the growth accelerates from the portion of the feature farthest from the field surface 502. This tungsten bulk fill growth profile creates bottom up growth in the subsequent processing and thus prevents the formation of a seam.

At activity 410, the method 400 comprises depositing a tungsten bulk fill 504 on the treated nucleation layer 506. As shown in FIG. 5D, tungsten is deposited in the feature 550 such that it fills the feature. Suitable methods for depositing the tungsten bulk fill 504 include CVD methods, ALD methods, pulsed tungsten or combinations thereof. The tungsten CVD process comprises concurrently flowing (co-flowing) a precursor gas, and a reducing agent. In at least one embodiment, co-flowing a precursor gas and a reducing agent can comprise alternating sequential repetitions of exposing the substrate to the precursor gas, and the reducing agent. The pulsed tungsten deposition comprises sequential repetitions of exposing the substrate to precursor gas, and then a reducing agent. The tungsten ALD process comprises sequential repetitions of exposing the substrate to a precursor gas, then exposing the substrate to a reducing agent. The method further includes purging the processing volume between exposing the substrate to the precursor gas, and the reducing agent by flowing an inert gas thereinto. In at least one embodiment, the precursor gas comprises WF₆ and the reducing agent comprises H₂.

These bulk fill methods form low stress tungsten fill 504 by lowering the pressure of the processing volume to between about 1 Torr and 300 Torr, while simultaneously increasing the processing temperature to about 400° C. and 550° C. In addition, these bulk fill methods form a seamless and voidless tungsten fill, by depositing tungsten into gap regions of the substrate in accordance with a deposition profile, such that the preferential nucleation site(s) for tungsten bulk fill 504 becomes the portion of the bottom of the feature, which is furthest away from the field surface. Since the inhibited nucleation layer, such as the WN layer, is formed on the upper sidewalls of the openings 503 and the field surface of the nucleation layer, the preferential nucleation site for tungsten bulk fill 504 becomes the bottom of the feature 550. As a result, the tungsten bulk fill 504 is deposited on the non-inhibited portions of the nucleation layer 506 to create a bottom up growth, in accordance with the inhibition profile. In some embodiments, the tungsten growth can result in some growth over a portion of the field. Typically, this growth is subject to subsequent processing such as chemical mechanical polishing (CMP).

In at least one embodiment, the tungsten CVD process includes concurrently flowing a tungsten-containing precursor gas, comprising WF₆, and a reducing agent, comprising H₂, into the processing volume and exposing the substrate thereto, wherein the flowrate of the tungsten-containing precursor, such as WF₆ into the processing volume is between about 100 sccm and 1000 sccm, or between about 200 sccm and 900 sccm, or for example between about 300 sccm and 800 sccm, and the flowrate of H₂ of is between about 500 sccm and 7000 sccm, or between about 750 sccm and 5500 sccm, or for example between 1000 sccm and 4000 sccm. In at least one embodiment, forming the tungsten bulk fill 504 includes heating the substrate to, and maintaining the substrate at, a temperature between about 100° C. and 1000° C., or between about 300° C. and 700° C., or for example between about 400° C. and 540° C. In some embodiments, forming the tungsten deposition process includes maintaining the processing volume at a pressure between about 900 mTorr and 120 Torr, or between about 1 Torr and 100 Torr, or between about 3 Torr and 70 Torr, or between about 4 Torr and 50 Torr, or for example between about 5 Torr and 30 Torr during the deposition process. Additionally, in some embodiments the grain size is between about 200 Å and 220 Å from calculation at 2000 Å film. In one example, the CVD process comprises, 1000 sccm and 4000 sccm, 400 C and 540 C and 5 Torr and 30 Torr. Running the process at a higher temperature range, such as a range of 400 C and 540 C, will increase the energy of the atoms as they contact the surface of the substrate during deposition, improving the surface diffusion and arrangement of the atoms within the crystalline structure. Additionally, running the process at lower pressures also reduces the deposition rate, thus also allowing the deposited atoms more time to find a preferred site within the crystalline structure.

In at least one embodiment, the pulsed tungsten deposition comprises sequential repetitions of exposing the substrate to precursor gas then a reducing agent. In some embodiments, the precursor gas comprises WF₆ and the reducing agent comprises H₂. The flowrate of WF₆ into the processing volume is between about 100 sccm and 2000 sccm, or between about 250 sccm and 1500 sccm, or for example between about 500 sccm and 900 sccm for a dose period of between about 1 second and 4 seconds. The flowrate of H₂ during the dose period is between about 500 sccm and 7000 sccm, or between about 750 sccm and 5500 sccm, or for example between 1000 sccm and 4000 sccm. In at least one embodiment, forming the tungsten bulk fill 504 includes heating the substrate to, and maintaining the substrate at, a temperature between about 100° C. and 1000° C., or between about 300° C. and 700° C., or for example between about 400° C. and 500° C. In some embodiments, forming the tungsten field layer includes maintaining the processing volume at a pressure between about 900 mTorr and 120 Torr, or between about 1 Torr and 100 Torr, or between about 2 Torr and 50 Torr, or for example between about 3 Torr and 10 Torr.

In at least one embodiment, the tungsten ALD process comprises sequential repetitions of exposing the substrate to precursor gas, then a reducing agent. The method further includes purging the processing volume between exposing the substrate to the precursor gas and the reducing agent by flowing an inert gas thereinto. In some embodiments, the precursor gas comprises WF₆ and the reducing agent comprises H₂. In at least one embodiment, the substrate with the nucleation layer deposited at low pressure has substantially lower stress than the substrate with the nucleation layer deposited at high pressure. Forming the tungsten layer includes heating the substrate to, and maintaining the substrate at, a temperature between about 100° C. and 1000° C., or between about 300° C. and 700° C., or preferentially between about 400° C. and 500° C. Here a typical flowrate for WF₆ to the processing volume is between about 1 sccm and 5000 sccm, or between about 250 sccm and 2500 sccm, or for example, between about 500 sccm and 900 sccm, for between about 1 second to 20 seconds, or between about 1 second to about 10 seconds, or for example, between about 1 second to 5 seconds. The flowrate for H₂ to the processing volume is between about 1 sccm and 10000 sccm, or between about 500 sccm and 6500 sccm, or for example, between about 1000 sccm and 4000 sccm, for between about 1 second to 20 seconds, or between about 1 second to about 10 seconds, or for example, between about 1 second to 5 seconds. Additionally, forming the tungsten field layer includes maintaining the processing volume at a pressure between about 900 mTorr and 50 Torr, or between about 1 Torr and 30 Torr, or between about 2 Torr and 20 Torr, or preferentially between about 3 Torr and 10 Torr. In at least one embodiment, the time for purging the processing volume between exposing the substrate to the WF₆ and H₂ precursor gases is between about 1 second and 20 seconds, or between 1 second and 10 seconds, or preferentially between about 1 second and 5 seconds.

At activities 412 and 414, the method 400 comprises forming a first overburden layer 530 of tungsten material on the tungsten fill layer and on the field surface of the substrate by forming a first overburden layer 530 on the fill layer, at activity 412, and forming a second overburden layer 540 on the first overburden layer, at activity 414. In some embodiments it is desirable to form a first and second overburden layer that has a low and compressive stress. Herein, forming one or both of the first overburden layer 530 and the second overburden layer 540 comprises process conditions which are different than those used to form the tungsten fill material disposed in the tungsten features. In some embodiments, the processes used to form the first or second overburden layers results in a higher material deposition rate than the process(es) used to form the tungsten fill material, thus reducing the substrate processing time and providing for desirably increased substrate throughput. In some embodiments, the methods used to form one or both of the first and second overburden layers allow for fine tuning of the stress in the resulting tungsten film which may be useful for controlling processing results at subsequent substrate processing operations, such as CMP processes.

Here, forming the first overburden layer 530 (FIG. 5E) at activity 412 comprises depositing a layer of tungsten on a surface of the tungsten bulk fill 504. Typically, forming the first overburden layer 530 eliminates the tungsten growth inhibition on the field surface which was provided by the radical treatment at activity 408. By reducing and/or reversing inhibition of tungsten growth on the field surface the field surface is prepared so as to allow for the growth and/or deposition of the second tungsten overburden layer 540.

Suitable methods for depositing the first overburden layer 530 include CVD methods, ALD methods, or combinations thereof. As previously mentioned, the tungsten CVD process comprises co-flowing a tungsten-containing precursor gas, such as WF₆, and a reducing agent, such as hydrogen (H₂) into the processing volume and exposing the substrate thereto. The tungsten ALD process comprises sequential repetitions of exposing the substrate to a precursor gas such as WF₆ then a reducing agent, such as H₂, and optionally purging the processing volume between exposing the substrate to the precursor gas and the reducing agent by flowing an inert gas thereinto. Here the first overburden layer 530, is used to initiate tungsten growth on the field surface of the substrate which was otherwise inhibited by the radical treatment operation described above.

In one embodiment, the CVD process for depositing the first overburden layer 530 includes co-flowing a tungsten-containing precursor gas, such as WF₆, and a reducing agent, such as hydrogen (H₂) into the processing volume and exposing the substrate thereto. Here, the processing volume is maintained at a pressure between about 900 mTorr and 1000 Torr, or between about 50 Torr and 700 Torr, or between about 100 Torr and 500 Torr, or for example, between about 150 Torr and 300 Torr. The substrate is heated to and/or maintained at a temperature between about 100° C. and 1000° C., such as between about 300° C. and 700° C. or for example, between about 450° C. and 540° C.

In another embodiment, the ALD process for forming the first overburden layer 530 includes alternating sequential repetitions of exposing the substrates to a tungsten-containing precursor gas and a reducing agent. Beneficially, the ALD process may be used to overcome the tungsten growth inhibition imparted by the radical treatment while providing a lower stress tungsten film than would be provided by relatively high pressure CVD process. In some of those embodiments, forming the tungsten nucleation layer further includes purging the processing volume between exposing the substrate to the tungsten-containing precursor gas and a reducing agent by flowing an inert gas into the processing volume while concurrently evacuating unreacted precursors and/or reaction byproducts therefrom. In some embodiments, the precursor gas includes WF₆ and the reducing agent includes H₂. Here, the deposited thin tungsten layer can have a final thickness of between about 5 Å and 100 Å, or between about 10 Å and 80 Å, or for example, between about 20 Å and 60 Å. Additionally, the processing volume is maintained at a pressure between about 900 mTorr and 100 Torr, or between about 3 Torr and 50 Torr, or between about 4 Torr and 40 Torr, or for example, between about 5 Torr and 20 Torr.

As previously mentioned, examples of suitable tungsten-containing precursors include tungsten halides, such as (WF₆) tungsten hexachlorids (WCl₆), and combinations thereof, and suitable hydrogen-containing reducing agents include boranes and silanes, e.g. B₂H₆, SiH₄, Si₂H₆, or combinations thereof. In at least one embodiment, the precursor gases comprise WF₆ and B₂H₆ or SiH₄ flowed into the processing volume and the exposed to the substrate thereto. Here a typical flowrate for WF₆ to the processing volume is between about 1 sccm and 1000 sccm, or between about 25 sccm and 500 sccm, or such as between about 50 sccm and 100 sccm. The typical flowrate for B₂H₆ to the processing volume is between about 1 sccm and 1000 sccm, or between about 100 sccm and 500 sccm, or for example, between about 200 sccm and 400 sccm. The typical flowrate for SiH₄ to the processing volume is between about 1 sccm and 1000 sccm, or between about 100 sccm and 500 sccm, or for example, between about 200 sccm and 400 sccm. Typically, the processing volume is maintained at a pressure between about 900 mTorr and 120 Torr, or between about 1 Torr and 100 Torr, or between about 3 Torr and 50 Torr, or for example, between about 5 Torr and 20 Torr.

Additionally, in some embodiments, the CVD process for depositing the first overburden layer 530 includes co-flowing a tungsten-containing precursor gas, such as WF₆, and a reducing agent, such as hydrogen (H₂) into the processing volume at a processing pressure at least three times greater than the processing pressure for depositing a tungsten bulk fill 504. Moreover, in some embodiments, the CVD process for depositing the first overburden layer 530 includes co-flowing a tungsten-containing precursor gas, such as WF₆ and a reducing agent, such as hydrogen (H₂) into the processing volume at a processing pressure at least two and a half times greater than the processing pressure for depositing a tungsten bulk fill 504. For example, in some embodiments, a ratio of the pressure of the processing volume for depositing the first overburden layer to the pressure of the processing volume for depositing the tungsten bulk fill 504 is about 1.25:1 or more, such as about 1.5:1 or more, about 1.75:1 or more, about 2:1 or more, about 2.25:1 or more, about 2.5:1 or more, about 2.75:1 or more, about 3:1 or more, about 3.25:1 or more, or about 3.5:1 or more.

In another embodiment, the ALD process for forming the first overburden layer 530 includes alternating sequential repetitions of exposing the substrate to a tungsten-containing precursor gas and a reducing agent at a processing pressure of about two times greater than the processing pressure for depositing a tungsten bulk fill 504. In yet another embodiment, the ALD process for forming the first overburden layer 530 includes alternating sequential repetitions of exposing the substrate to a tungsten-containing precursor gas and a reducing agent at a processing pressure of about one and a half times greater than the processing pressure for depositing a tungsten bulk fill 504. For example, in some embodiments, the pressure of the processing volume for depositing the first overburden layer to the pressure of the processing volume for depositing the tungsten bulk 504 has a ratio of about 1.25:1 or more, about 1.50:1 or more, about 1.75:1 or more, about 2:1 or more, about 2.25:1 or more.

At activity 414, the method 400 comprises forming the second overburden layer 540, wherein forming the second overburden layer 540 comprises depositing a tungsten field layer onto the first overburden layer 530. Here, the second overburden layer is deposited using processing conditions which provide for a relativity low stress tungsten. Suitable methods for depositing the second overburden layer include CVD methods, ALD methods, and pulsed W or combinations thereof.

Typically, a chemical mechanical polishing (CMP) process is used to remove an overburden of tungsten material (and the barrier layer disposed there below) from the field surface of the substrate following a tungsten bulk fill of the feature. Generally, such CMP processes rely on a combination of chemical and mechanical activity to facilitate uniform removal of the overburden layer and an endpoint detection method to determine when the tungsten overburden has cleared from the field surface. Non-uniform clearing of tungsten from the field surface or failure to detect a polishing endpoint, can result in undesired over-polishing or under-polishing of at least some regions of the substrate surface. Tungsten over-polishing can cause undesired removal of tungsten from the tungsten feature, e.g. feature coring, because the polishing fluid in a CMP process is often corrosive, and can cause damage to the features during over polishing. Tungsten under-polishing can result in undesired residual tungsten remaining on the field surface following CMP. Unfortunately, the inhibition treatments used to provide seam-free and void-free tungsten features by promoting bottom up growth of tungsten also inhibit the growth of tungsten on the field surface to prevent the overburden of tungsten from forming during the bulk tungsten process. Thus, the embodiments herein include methods of depositing an overburden layer, which are different from the methods used to deposit the bulk fill layer, which provide a uniform thickness of tungsten on the field surface of the substrate following the radical inhibition treatment described at 408.

In one embodiment, a tungsten CVD process for depositing the second overburden layer 540 includes co-flowing a tungsten-containing precursor and a reducing agent into the processing volume and exposing the surface of the second tungsten nucleation layer thereto. In some embodiments, the precursor gas includes WF₆ and the reducing agent includes H₂. Forming the tungsten field layer includes heating the substrate to, and maintaining the substrate at, a temperature between about 100° C. and 1000° C., or between about 300° C. and 700° C., or for example, between about 400° C. and 540° C. In some embodiments, forming the tungsten field layer includes maintaining the processing volume at a pressure between about 900 mTorr and 120 Torr, or between about 1 Torr and 100 Torr, or between about 3 Torr and 70 Torr, or between about 4 Torr and 50 Torr, or for example, between about 5 Torr and 30 Torr. Here a typical flowrate for WF₆ to the processing volume is between about 10 sccm and 1500 sccm, or between about 150 sccm and 1000 sccm, or for example, between about 300 sccm and 800 sccm. The typical flowrate for H₂ to the processing volume is between about 100 sccm and 10000 sccm, or between about 500 sccm and 7500 sccm, or for example, between about 1000 sccm and 4000 sccm.

Additionally, in some embodiments, the CVD process for depositing the second overburden layer 540 includes co-flowing a tungsten-containing precursor gas, such as WF₆, and a reducing agent, such as hydrogen (H₂) into the processing volume at a processing pressure at least four times less than the processing pressure for depositing the first overburden layer 530. For example, in some embodiments, a ratio of the pressure of the processing volume for depositing the second overburden layer 540 to the pressure of the processing volume for depositing the first overburden layer 530 is about 1:5 or less, such as about 1:4.5 or less, such as about 1:4 or less, such as about 1:3.5 or less, such as about 1:3 or less, such as about 1:2.5 or less, such as about 1:2 or less.

In one embodiment, a tungsten ALD process for forming a second overburden layer 540 comprises exposing the substrate to sequential repetitions of a tungsten precursor gas and a reducing agent, and optionally purging the processing volume between exposing the substrate to the precursor gases by flowing an inert gas thereinto. In some embodiments, the precursor gas includes WF₆ and the reducing agent includes H₂. In at least one embodiment, the substrate with the nucleation layer deposited at low pressure has substantially lower stress than the substrate with the nucleation layer deposited at high pressure. Forming the tungsten field layer includes heating the substrate to, and maintaining the substrate at, a temperature between about 100° C. and 1000° C., or between about 300° C. and 700° C., or for example, between about 400° C. and 500° C. Here a typical flowrate for WF₆ to the processing volume is between about 1 sccm and 5000 sccm, or between about 250 sccm and 2500 sccm, or for example, between about 500 sccm and 900 sccm, for between about 1 second to 20 seconds, or between about 1 second to about 10 seconds, or for example, between about 1 second to 5 second. The typical flowrate for H₂ to the processing volume is between about 1 sccm and 10000 sccm, or between about 500 sccm and 6500 sccm, or for example, between about 1000 sccm and 4000 sccm, for between about 1 second to 20 seconds, or between about 1 second to about 10 seconds, or for example, between about 1 second to 5 second. Additionally, forming the second overburden layer 540 includes maintaining the processing volume at a pressure between about 900 mTorr and 50 Torr, or between about 1 Torr and 30 Torr, or between about 2 Torr and 20 Torr, or for example, between about 3 Torr and 10 Torr. In at least one embodiment, the time for purging the processing volume between exposing the substrate to the WF₆ and H₂ precursor gasses is between about 1 second and 50 seconds, or between 1 second and 25 seconds, or for example, between about 1 second and 4 seconds.

Additionally, in some embodiments, the ALD process for forming the second overburden layer 540 comprises maintaining the processing volume at a processing pressure at least ten times less than the processing pressure for depositing the first overburden layer 530. For example, in some embodiments, a ratio of the pressure of the processing volume for depositing the second overburden layer 540 to the pressure of the processing volume for depositing the first overburden layer 530 is about 1:10 or less, such as about 1:9 or less, such as about 1:8 or less, such as about 1:7 or less, such as about 1:6 or less, such as about 1:5 or less, such as about 1:4 or less.

In one embodiment, the pulsed tungsten deposition process for depositing a second overburden layer 540 comprises sequential repetitions of exposing a tungsten precursor gas and then a reducing agent. In some embodiments the precursor gas includes WF₆, and the reducing agent includes H₂. Here a typical flowrate for WF₆ to the processing volume is between about 1 sccm and 5000 sccm, or between about 250 sccm and 2500 sccm, or for example, between about 500 sccm and 900 sccm. The typical flowrate for H₂ to the processing volume is between about 1 sccm and 10000 sccm, or between about 500 sccm and 6500 sccm, or for example, between about 1000 sccm and 4000 sccm.

Additionally, in some embodiments, the pulsed tungsten deposition process for depositing the second overburden layer 540 comprises maintaining the processing volume at a processing pressure at least ten times less than the processing pressure for depositing the first overburden layer 530. For example, in some embodiments, a ratio of the pressure of the processing volume for depositing the second overburden layer 540 to the pressure of the processing volume for depositing the first overburden layer 530 is about 1:10 or less, such as about 1:9 or less, such as about 1:8 or less, such as about 1:7 or less, such as about 1:6 or less, such as about 1:5 or less, such as about 1:4 or less.

For example, a tungsten feature was formed using a tungsten CVD process that comprised concurrently flowing a tungsten-containing precursor gas WF₆, and a reducing agent H₂, into the processing volume and exposing the surface of the second tungsten nucleation layer thereto. The tungsten CVD included heating the substrate to a process temperature of about 450° C., with a stress of about 1000 MPa and processing volume at a pressure of about 5 Torr and 30 Torr.

In another example, a tungsten feature was formed using a tungsten CVD process that comprised concurrently flowing a tungsten-containing precursor gas WF₆, and a reducing agent H₂, into the processing volume and exposing the surface of the second tungsten nucleation layer thereto. The tungsten CVD included heating the substrate to a process temperature of about 540° C., with a stress of about 540 MPa, and a processing volume at a pressure of between about 5 Torr and 30 Torr.

In yet another example, a tungsten feature was formed using a pulsed tungsten deposition process. The pulsed tungsten deposition comprised sequential repetitions of exposing the substrate to a precursor gas WF₆, and then a reducing agent H₂. Here, the pulsed tungsten deposition included heating the substrate to a process temperature of about 400° C., with a stress of about 673 MPa, and a processing volume at a pressure of between about 3 Torr and 10 Torr. In this example, the tungsten growth rate on surfaces of the upper portions of the openings is less than the tungsten growth rate on surfaces in the lower portions of the openings which provides for bottom-up tungsten formation in the feature. Because the tungsten growth is predominantly from the bottom of the feature, the seams that would otherwise result from conformal growth from the sidewalls of the feature can be avoided. Similarly, bottom up tungsten growth does not have the problem of creating overhangs of tungsten material, e.g., pinch points, at the opening to the feature, thus eliminating undesirable voids associated therewith.

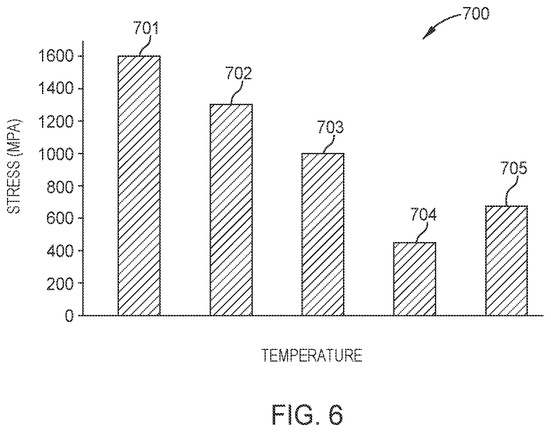

As can be seen in the previous examples, the methods described herein advantageously provide for seam-free and void-free tungsten bulk fill of high aspect ratio features. FIG. 6 is a graph showing the film stress of bulk layers of tungsten deposited according to various methods disclosed herein. All layers are deposited to a thickness of 1,200 Angstroms (Å).

Tungsten bulk fill layer 601 was deposited by concurrently flowing the tungsten-containing precursor gas WF₆, and the reducing agent H₂, into the processing volume and exposing the surface of a tungsten nucleation layer to the tungsten-containing precursor gas and the reducing agent. Here the flowrate for WF₆ to the processing volume was between about 150 sccm and 750 sccm, and the flowrate for H₂ to the processing volume was between about 1500 sccm and 5000 sccm. Here, the substrate was maintained at a process temperature of between about 150° C. and 750° C., and the chamber was maintained at a pressure of between about 100 Torr and 500 Torr. A blanket tungsten layer was deposited to a thickness of approximately 1,200 Å, and a stress measured for the resulting film was approximately 1600 MPa.

Tungsten bulk fill layer 602 was deposited by concurrently flowing the tungsten-containing precursor gas WF₆, and a reducing agent H₂, into the processing volume and exposing the surface of the tungsten nucleation layer to the tungsten-containing precursor gas and the reducing agent. Here, the flowrate for WF₆ to the processing volume was between about 300 sccm and 800 sccm, and the flowrate for H₂ to the processing volume was between about 1000 sccm and 4000 sccm. Here, the substrate was maintained at a process temperature of between about 375° C. and about 425° C., and the chamber was maintained at a pressure of between about 5 Torr and 30 Torr. A blanket tungsten layer was deposited to a thickness of approximately 1,200 Å, and a stress measured for the resulting film was approximately 1300 MPa.

Tungsten bulk fill layer 603 was deposited by concurrently flowing the tungsten-containing precursor gas WF₆, and the reducing agent H₂, into the processing volume and exposing the surface of the tungsten nucleation layer to the tungsten-containing precursor gas and the reducing agent. Here, the flowrate for WF₆ to the processing volume was between about 300 sccm and 800 sccm, and the flowrate for H₂ to the processing volume was between about 1000 sccm and 4000 sccm. Here, the substrate was maintained at a process temperature of between about 425° C. and 475° C., and the chamber was maintained at a pressure of between about 5 Torr and 30 Torr. A blanket tungsten layer was deposited to a thickness of approximately 1,200 Å, and a stress measured for the resulting film was approximately 1000 MPa.

Tungsten bulk fill layer 604 was deposited by concurrently flowing the tungsten-containing precursor gas WF₆, and the reducing agent H₂, into the processing volume and exposing the surface of the tungsten nucleation layer to the tungsten-containing precursor gas and the reducing agent. Here, the flowrate for WF₆ to the processing volume was between about 300 sccm and 800 sccm, and the flowrate for H₂ to the processing volume was between about 1000 sccm and 4000 sccm. Here, the substrate was maintained at a process temperature of between about 500° C. and 550° C., and the chamber was maintained at a pressure of between about 5 Torr and 30 Torr.

A blanket tungsten layer was deposited to a thickness of approximately 1,200 Å, and a stress measured for the resulting film was approximately 450 MPa.

Tungsten bulk fill layer 605 was deposited by pulsed tungsten deposition that comprised sequential repetitions of exposing the substrate to the tungsten precursor gas WF₆, and then the reducing agent H₂. Here, the flowrate for WF₆ to the processing volume was between about 500 sccm and 900 sccm, and the flowrate for H₂ to the processing volume was about 1000 sccm and 4000 sccm. Here, the substrate was maintained at a process temperature between about 375° C. and about 425° C., and the chamber was maintained at a pressure of between about 3 Torr and 10 Torr. A blanket tungsten layer was deposited to a thickness of approximately 1,200 Å, and a stress measured for the resulting film was approximately 673 MPa.

As can be seen in the graph, the process used to deposit tungsten at FIG. 604 results in tungsten stress reduced by three times when compared to the tungsten deposition of 601. Thus, in some embodiments one or both of the tungsten bulk fill or the second overburden layer has a film stress of less than 1600 MPa, less than 1500 MPa, less than 1400 MPa, less than 1300 MPa, less than 1200 MPa, less than 1100 MPa, 1000 MPa, less than 900 MPa, less than 800 MPa, less than 700 MPa, less than 600 MPa.

### CONCLUSION

Embodiments of the present disclosure generally provide methods and systems of depositing seamless and/or voidless tungsten fill, by treating the nucleation layer with a radical species to slow deposition of tungsten on the treated surface. Although the foregoing embodiments have been described in some detail, certain changes and modifications may be practiced within the scope of the claims. Accordingly, the present embodiments are to be considered as illustrative and not restrictive, as other and further embodiments of the disclosure may be devised without departing from the basic scope thereof. The basic scope thereof is determined by the claims that follow.

1. A method of depositing a film, comprising:
depositing a tungsten bulk fill material into a plurality of openings on a substrate by exposing the substrate to a first tungsten-containing precursor gas and a first reducing agent at or below a first processing pressure, the substrate comprising a first material layer having the plurality of openings formed therein and a tungsten nucleation layer formed on the first material layer and conformally lining the plurality of openings; and
depositing a first tungsten overburden layer over the tungsten bulk fill material comprising exposing the substrate to a second tungsten-containing precursor gas and a second reducing agent at a second processing pressure, wherein
the second processing pressure is at least three times greater than the first processing pressure.

2. The method of claim 1, further comprising exposing the tungsten nucleation layer to a radical species of a treatment gas to selectively inhibit deposition of the tungsten bulk fill material on a field surface of the tungsten nucleation layer relative to deposition of the tungsten bulk fill material on surfaces within the plurality of openings.

3. The method of claim 1, wherein the first processing pressure is about 50 Torr or less.

4. The method of claim 1, wherein exposing the substrate to the second tungsten-containing precursor gas and the second reducing agent to deposit the first tungsten overburden layer comprises exposing the substrate to alternating pulses of the second tungsten-containing precursor gas and the second reducing agent.

5. The method of claim 1, wherein exposing the substrate to the second tungsten-containing precursor gas and the second reducing agent to deposit the first tungsten overburden layer comprises concurrently exposing the substrate to the second tungsten-containing precursor gas and the second reducing agent.

6. The method of claim 1, further comprising depositing a second tungsten overburden layer on the first tungsten overburden layer, comprising:
concurrently exposing the substrate to a third tungsten-containing precursor gas and a third reducing agent at a third processing pressure, wherein
the second processing pressure is at least four times greater than the third processing pressure.

7. The method of claim 1, further comprising depositing a second tungsten overburden layer on the first tungsten overburden layer, comprising exposing the substrate to alternating pulses of a third tungsten-containing precursor gas and a third reducing agent at a third processing pressure, wherein
the second processing pressure is at least three times greater than the third processing pressure.

8. The method of claim 7, wherein depositing the second tungsten overburden layer further comprises:
flowing an inert purge gas in between alternating pluses of the third tungsten-containing precursor gas and the third reducing agent.

9. A method of depositing a film, comprising:
depositing a tungsten bulk fill material into a plurality of openings formed in a first material layer of a substrate by concurrently flowing a first tungsten-containing precursor gas, and a first reducing agent, into a first processing volume, and exposing the substrate thereto while maintaining the first processing volume at a first processing pressure; and
depositing a first tungsten overburden layer onto the tungsten bulk fill material and a field surface of the substrate comprising exposing the substrate to alternating pulses of a second tungsten-containing precursor gas and a second reducing agent in a second processing volume while maintaining the second processing volume at a second processing pressure, wherein
the second processing pressure is at least three times greater than the first processing pressure.

10. The method of claim 9, wherein the first reducing agent comprises hydrogen gas (H₂), and the second reducing agent comprises diborane gas, a silane-containing gas, or a combination thereof.

11. The method of claim 9, wherein depositing the first tungsten overburden layer comprises concurrently flowing the second tungsten-containing precursor gas, and the second reducing agent, into the second processing volume and exposing the substrate thereto, while maintaining the second processing volume at a pressure of between about 150 Torr and about 300 Torr.

12. The method of claim 9, further comprising depositing a second tungsten overburden layer on the first tungsten overburden layer comprising concurrently flowing a third tungsten-containing precursor gas, and a third reducing agent, into the second processing volume while maintaining the second processing volume at a pressure of between about 900 mTorr and about 100 Torr.

13. The method of claim 9, further comprising depositing a second tungsten overburden layer comprising sequential repetitions of:
(a) exposing the substrate to a third tungsten-containing precursor gas; and
(b) exposing the substrate to a third reducing agent.

14. The method of claim 13, further comprising:
(c) flowing a purge gas into the second processing volume between (a) and (b).

15. The method of claim 9, further comprising exposing a substrate to a radical species of a treatment gas prior to depositing the tungsten bulk fill material, the substrate further comprising a tungsten nucleation layer formed on the first material layer and conformally lining the plurality of openings, wherein exposing the substrate to the radical species forms an inhibition profile to inhibit the deposition of the tungsten bulk fill material on a field surface of the tungsten nucleation layer relative to deposition of the tungsten bulk fill material on surfaces within the plurality of openings.

16. The method of claim 15, wherein forming the radical species comprises:
flowing the treatment gas into a processing volume;
igniting and maintaining a treatment plasma of the treatment gas; and
exposing the substrate to the treatment plasma.

17. A substrate processing system, comprising:
a first process chamber, a second process chamber, and a transfer chamber coupling the first process chamber to the second process chamber; and
a non-transitory computer readable medium having instructions stored thereon for performing a method of processing a substrate when executed by a processor, the method comprising:
depositing, using the first process chamber, a barrier material layer onto the substrate, wherein the substrate comprises a material layer having a plurality of openings formed therein;
depositing, a tungsten bulk fill material into the plurality of openings using the second process chamber, by exposing the substrate to a first tungsten-containing precursor gas and a first reducing agent at or below a first processing pressure; and
depositing a first tungsten overburden layer over the tungsten bulk fill material comprising exposing the substrate to a second tungsten-containing precursor gas, and a second reducing agent at a second processing pressure, wherein
the second processing pressure is at least three times greater than the first processing pressure.

18. The substrate processing system of claim 17, further comprising depositing a tungsten nucleation layer and exposing the tungsten nucleation layer to a radical species of a treatment gas before depositing the tungsten bulk fill material.

19. The substrate processing system of claim 17, wherein depositing a tungsten bulk fill material into the plurality of openings comprises:
concurrently flowing a tungsten-containing precursor gas, and a reducing agent, into a processing volume and exposing the substrate thereto, wherein the tungsten-containing precursor gas is flowed at a pressure of between about 900 mTorr and 100 Torr.

20. The substrate processing system of claim 17, wherein depositing a tungsten bulk fill material into the plurality of openings comprises:
exposing the substrate to sequential repetitions of a precursor gas, and a reducing agent, and wherein the precursor gas is flowed at a pressure of between about 900 mTorr and 100 Torr.
